(19) United States
(12) Patent Application Publication
(10) Pub. No.: US 2018/0158748 A1
(43) Pub. Date: Jun. 7, 2018

(54) HEAT DISSIPATION APPARATUS FOR SEMICONDUCTOR MODULE

(71) Applicant: Oh Jung Kwon, (US)

(72) Inventors: Oh Jung KWON, Paju (KR); Sang Ho JEON, Goyang (KR)

(21) Appl. No.: 15/659,222

(22) Filed: Jul. 25, 2017

(30) Foreign Application Priority Data
Dec. 1, 2016 (KR) 10-2016-0162989

(51) Int. Cl. H01L 23/367; H01L 23/373; F28F 3/02; H01L 23/427; H05K 7/20

(52) U.S. Cl. CPC H01L 23/3675; H01L 23/373; H05K 7/2089; F28F 3/02; H01L 23/427; H01L 23/3672

(57) ABSTRACT

A heat dissipation apparatus for a semiconductor module according to an exemplary embodiment of the present invention includes: a heatsink which is provided to be in surface-to-surface contact with a semiconductor module; a duct unit which includes a pair of wall members which extends perpendicularly to an edge of the other surface of the heatsink and a quadrangular box member which is formed in a quadrangular box shape opened at both ends thereof, in which two sides of the opened ends of the quadrangular box member are connected to the wall members, respectively, and any one surface, among surfaces for constituting the quadrangular box shape, is formed to be inclined; and an intake fan which is provided at the other end of the quadrangular box member, in which a vent hole is formed in the inclined lateral surface of the quadrangular box member.

### CROSS-REFERENCE TO RELATED APPLICATIONS

This application claims priority to and the benefit of Korean Patent Application No. 10-2016-0162989 filed in the Korean Intellectual Property Office on Dec. 1, 2016, the entire contents of which are incorporated herein by reference.

### TECHNICAL FIELD

The present invention relates to a heat dissipation apparatus for a semiconductor module.

### BACKGROUND ART

Most electric power apparatuses (e.g., electric power converters) include a semiconductor module and a heat dissipation apparatus (cooling apparatus), and a semiconductor element for controlling electric power of the semiconductor module generates a large amount of heat during operation. Because the high-temperature heat affects a lifespan and an operation of an electronic product, the heat dissipation apparatus is configured to dissipate heat generated by the semiconductor element.

The heat dissipation apparatus in the related art is structured to be disposed on the other surface of a circuit board which is opposite to one surface of the circuit board on which semiconductor elements or control elements of the semiconductor module are mounted, and the heat dissipation apparatus is made of a conductive material so as to dissipate heat generated by the semiconductor elements.

Among various types of heat dissipation apparatuses in the related art, there are a structure with a heat pipe, a water-cooled structure, and a structure with heat radiating fins.

In the case of the heat dissipation apparatus in the related art, the number of semiconductor elements disposed in the same space is increased because of semiconductor modularization, and as a result, a large amount of heat is generated in the semiconductor module. Therefore, the heat dissipation apparatus needs to be manufactured to have a larger size in order to increase a heat dissipation region and thus to dissipate heat generated by the semiconductor module that generates a large amount of heat.

However, a mere increase in size of the heat dissipation apparatus does not lead to efficient heat dissipation but rather increases an overall size of the electric power apparatus. Further, there is no solution for dissipating heat discharged to the surface of the circuit board, and as a result, there is a problem in that performance of the semiconductor element deteriorates due to heat on the surface of the circuit board.

### SUMMARY OF THE INVENTION

The present invention has been made in an effort to provide a heat dissipation apparatus for a semiconductor module which is capable of effectively dissipating heat on a circuit board by applying a duct structure.

An exemplary embodiment of the present invention provides a heat dissipation apparatus for a semiconductor module, the heat dissipation apparatus including: a heatsink which is provided to be in surface-to-surface contact with a semiconductor module; a duct unit which includes a pair of wall members which extends perpendicularly to an edge of the other surface of the heatsink from the edge of the other surface of the heatsink which is opposite to one surface of the heatsink which is in surface-to-surface contact with the semiconductor module, and a quadrangular box member which is formed in a quadrangular box shape opened at both ends thereof, in which two sides of the opened ends of the quadrangular box member are connected to the wall members, respectively, and any one surface, among surfaces for constituting the quadrangular box shape, is formed to be inclined; and an intake fan which is provided at the other end of the quadrangular box member, in which a vent hole is formed in the inclined lateral surface of the quadrangular box member so that the wind generated by the intake fan passes through the quadrangular box member and is provided to the semiconductor module when the intake fan operates to dissipate heat of the semiconductor module.

The number of vent holes may be more than one.

The plurality of vent holes may be formed on the same line as an imaginary surface that horizontally extends from one surface of the heatsink, and the plurality of vent holes may be arranged in a row in a longitudinal direction of the inclined lateral surface of the quadrangular box member.

Each of the plurality of vent holes may be formed in a circular or elliptical shape.

Each of the plurality of vent holes may have a maximum diameter equal to a thickness of the semiconductor module.

The duct unit may further include an auxiliary duct which guides a flow path of the wind passing through the vent hole and is formed on the inclined lateral surface of the quadrangular box member so as to surround the vent hole.

The auxiliary duct may include: a pair of triangular members which is provided on the inclined lateral surface of the quadrangular box member so as to be spaced apart from each other at a predetermined interval; and a guide surface which connects the pair of triangular members and is formed on the same plane as an imaginary surface that horizontally extends from an upper end of the semiconductor module which is opposite to a lower end of the semiconductor module being in surface-to-surface contact with one surface of the heatsink.

An auxiliary vent hole may be formed in the guide surface to adjust intensity of the wind passing through the vent hole, and the auxiliary vent hole may be opened and closed by a cover.

The duct unit may further include an opening and closing member which is slidably connected to the inclined lateral surface of the quadrangular box member and opens and closes the vent hole.

The number of opening and closing members may be more than one so as to open and close the vent hole to a predetermined degree.

One surface of the heatsink may be divided into a first region which occupies at least a part of one surface of the heatsink, and a second region which occupies the remaining part of one surface of the heatsink, the semiconductor module may be provided in the first region, and a heat radiating plate may be provided in the second region.

The heat dissipation apparatus may further include a casing which is coupled to an edge of one surface of the heatsink so as to surround the semiconductor module and the heat radiating plate.

The casing may have an exhaust port.

An exhaust fan may be provided in the exhaust port so that the wind generated by the intake fan passes through the vent hole, passes through an upper region of one surface of the heatsink, and is discharged through the exhaust port.

The heatsink may include: a base which has one surface formed to be in surface-to-surface contact with the semiconductor module; and a plurality of heat radiating fins which extends perpendicularly to the other surface of the base from the other surface of the base which is opposite to one surface of the base.

Therefore, according to the heat dissipation apparatus for a semiconductor module according to the exemplary embodiment of the present invention, the wind generated by the intake fans may pass through the vent hole of the quadrangular box member and may be provided concentratedly to the vicinity of the semiconductor element of the semiconductor module, such that heat generated by the semiconductor element is effectively dissipated, and as a result, it is possible to prevent performance of the semiconductor module from deteriorating due to heat.

The heat radiating plate is provided in a predetermined region remaining on one surface of the heatsink to which the semiconductor module is attached, and as a result, it is possible to more effectively dissipate heat of the semiconductor module.

Heat of a bus bar may be effectively dissipated by the structure including the casing and the exhaust fan, and as a result, it is possible to prevent performance of the semiconductor module from deteriorating due to the heat of the bus bar.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a perspective view of a heat dissipation apparatus for a semiconductor module according to an exemplary embodiment of the present invention.

FIG. 2 is a partial perspective view of the heat dissipation apparatus for a semiconductor module according to the exemplary embodiment of the present invention.

FIG. 3 is a side view of the heat dissipation apparatus for a semiconductor module according to the exemplary embodiment of the present invention.

FIG. 4 is a perspective view of the heat dissipation apparatus for a semiconductor module having a casing according to the exemplary embodiment of the present invention.

FIG. 5 is a perspective view of the heat dissipation apparatus for a semiconductor module from which the casing in FIG. 4 is removed.

FIG. 6 is a partial perspective view of the heat dissipation apparatus for a semiconductor module having a bus bar according to the exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout several figures of the drawing.

### DETAILED DESCRIPTION

Hereinafter, exemplary embodiments of the present invention will be described in detail with reference to the accompanying drawings.

In order to sufficiently understand the object that will be achieved by the present invention, advantages in operation of the present invention, and implementation of the present invention, reference needs to be made to the accompanying drawings for illustrating an exemplary embodiment of the present invention and contents disclosed in the accompanying drawings.

Hereinafter, an exemplary embodiment of the present invention will be described in detail with reference to the accompanying drawings. However, the present invention may be modified in various different ways, and is not limited to the exemplary embodiment to be described below. Further, a part irrelevant to the description will be omitted to clearly describe the present disclosure, and the same constituent elements will be designated by the same reference numerals.

Unless explicitly described to the contrary, the word “comprise” and variations such as “comprises” or “comprising”, will be understood to imply the inclusion of stated elements but not the exclusion of any other elements. In addition, the term “unit”, “part”, “module”, “block”, or the like, which is described in the specification, means a unit that performs at least one function or operation, and may be implemented by hardware, software, or a combination of hardware and software.

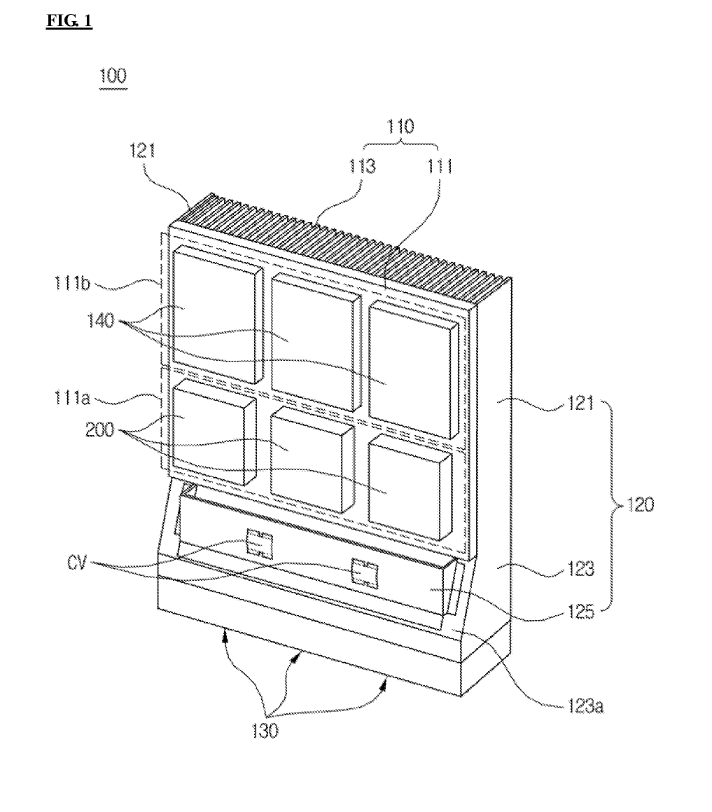

Referring to FIGS. 1 to 4, a heat dissipation apparatus 100 for a semiconductor module according to an exemplary embodiment of the present invention prevents performance of semiconductor modules 200 from deteriorating due to heat generated by semiconductor elements of the semiconductor modules 200, and the heat dissipation apparatus 100 may include a heatsink 110, a duct unit 120, intake fans 130, heat radiating plates 140, a casing 150, and an exhaust fan 160. Here, the semiconductor module 200 may include a semiconductor element for electric power conversion which converts or controls electric power in accordance with a system to which the semiconductor module 200 is applied, but the present invention is not limited thereto, and the semiconductor module 200 may include various semiconductor elements.

In the heat dissipation apparatus 100 for a semiconductor module according to the exemplary embodiment of the present invention, the heatsink 110 is provided to be in surface-to-surface contact with the semiconductor module 200, the duct unit 120 is appropriately provided on the heatsink 110, the duct unit 120 includes a pair of wall members 121 and a quadrangular box member 123, the intake fans 130 are provided in the quadrangular box member 123, any one surface of the surfaces for constituting the quadrangular box member 123 is formed to be inclined, and vent holes Vt are formed in the inclined lateral surface of the quadrangular box member 123. Therefore, when the intake fans 130 operate to dissipate heat generated by the semiconductor module 200, the wind generated by the intake fans 130 passes through the vent holes Vt of the quadrangular box member 123 and moves toward an upper side of one surface of the heatsink 110, thereby dissipating heat generated by the semiconductor modules 200.

Therefore, according to the heat dissipation apparatus 100 for a semiconductor module according to the exemplary embodiment of the present invention, the wind generated by the intake fans 130 may be provided concentratedly to the vicinity of the semiconductor elements of the semiconductor modules 200 while passing through the vent holes Vt of the quadrangular box member 123, such that heat generated by the semiconductor element is effectively dissipated, and as a result, it is possible to prevent performance of the semiconductor module 200 from deteriorating due to heat.

Hereinafter, a configuration of the heat dissipation apparatus 100 for a semiconductor module according to the exemplary embodiment of the present invention will be described in detail.

Referring to FIG. 1, the heatsink 110 is provided to be in surface-to-surface contact with the semiconductor modules 200, and prevents an increase in temperature of the semiconductor modules 200 by receiving and dissipating heat generated by the semiconductor modules 200, and the heatsink 110 may include a base 111 and a plurality of heat radiating fins 113.

The base 111 may have a quadrangular plate shape. The base 111 may be made of a conductive material with high thermal conductivity. The semiconductor module 200 may be attached to one surface of the base 111 so as to be in surface-to-surface contact with one surface of the base 111. For example, the semiconductor module 200 includes a circuit board, circuit wiring formed on the circuit board, and semiconductor elements mounted on the circuit board so as to be connected to the circuit wiring. The semiconductor elements may be mounted on one surface of the circuit board of the semiconductor module 200, and an insulating plate and a metal plate abutting against the insulating plate may be provided on the other surface of the circuit board which is opposite to one surface of the circuit board.

That is, the metal plate of the semiconductor module 200 may be attached to one surface of the base 111 so as to be in surface-to-surface contact with one surface of the base 111. The heat generated by the semiconductor module 200 may be transferred to the base 111 through the metal plate and then dispersed to the plurality of heat radiating fins 113.

The plurality of heat radiating fins 113 may extend to be perpendicular to the other surface of the base 111 from the other surface of the base 111 which is opposite to one surface of the base 111. Here, the heatsink 110 is not limited to an extruded shape of the heat radiating fin, but may be substituted by a heat pipe and a water-cooled heatsink.

Meanwhile, one surface of the base 111 may be divided into a first region 111a which occupies at least a part of one surface of the base 111, and a second region 111b which occupies the remaining part of one surface of the base 111. The plurality of (e.g., three) semiconductor modules 200 may be attached to the first region 111a. Here, the number of semiconductor modules 200 may be increased or decreased as necessary.

The reason why the base 111 is configured to have the second region 111b in addition to the first region 111a to which the semiconductor modules 200 are attached is to improve a heat dissipation effect by dissipating heat generated by the semiconductor modules 200 to a larger area. In this case, the heat radiating plates 140 may be provided in the second region 111b of the base 111.

The heat radiating plate 140 may be made of a metallic material with high thermal conductivity. The heat radiating plate 140 may be manufactured to have a quadrangular plate shape by a manufacturing method such as extrusion and die casting. The heat radiating plate 140 may be attached to the second region 111b of one surface of the base 111 by a bonding method such as brazing. The plurality of (e.g., three) heat radiating plates 140 may be attached, but the present invention is not limited thereto, and three or more or less heat radiating plates 140 may be attached. In this case, heat radiating grease may be applied onto one surface of the heat radiating plate 140 attached to the second region 111b, and the heat radiating grease may prevent deterioration in thermal conductivity between the heat radiating plate 140 and the base 111.

Referring to FIGS. 1 to 3, and 5, the duct unit 120 serves to guide a flow path of the wind, which discharges heat to the outside, in order to prevent heat generated by the semiconductor module 200 from remaining in the heatsink 110 and the heat radiating plate 140 after the heat is dissipated, and the duct unit 120 may include the pair of wall members 121, the quadrangular box member 123, an auxiliary duct 125, and opening and closing members 127.

The pair of wall members 121 may extend perpendicular to the other surface of the base 111 from an edge of the other surface of the base 111 which is opposite to one surface of the base 111 which is in surface-to-surface contact with the semiconductor modules 200. The pair of wall members 121 may guide the wind so that the wind flows between the heat radiating fins 113 of the heatsink 110. Here, unlike the base 111, the pair of wall members 121 may be made of an insulating material.

The quadrangular box member 123 may be formed to have a quadrangular box shape opened at both ends thereof. Among four surfaces that constitute the quadrangular box shape of the quadrangular box member 123, any one surface 123a may be formed to be inclined. Here, an inclination angle of the inclined lateral surface 123a of the quadrangular box member 123 may be appropriately set by a user as necessary.

Two sides of the opened ends of the quadrangular box member 123 may be connected to the wall members 121, respectively. The quadrangular box member 123 may be formed integrally with the pair of wall members 121, but the present invention is not limited thereto. Thereafter, the wind generated by the intake fans 130 passes through the quadrangular box member 123 and flows between the heat radiating fins 113 of the heatsink 110, thereby discharging heat of the heatsink 110 to the outside.

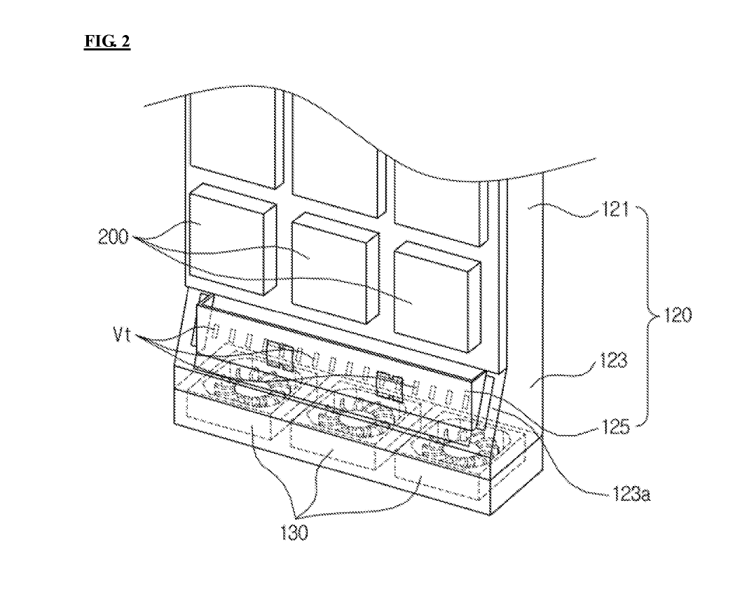

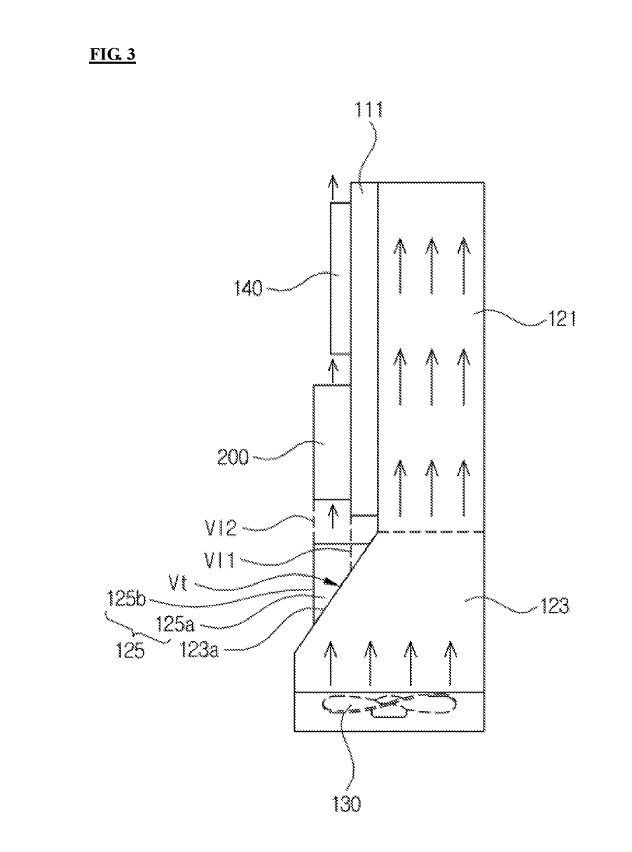

In FIGS. 2 and 3, the plurality of vent holes Vt may be formed in the inclined lateral surface 123a of the quadrangular box member 123. The plurality of vent holes Vt may be formed in the inclined lateral surface 123a of the quadrangular box member 123, such that the plurality of vent holes Vt may be formed on the same line as a first imaginary surface V11 that horizontally extends from one surface of the base 111. The plurality of vent holes Vt may be arranged in a row in a longitudinal direction of the inclined lateral surface 123a of the quadrangular box member 123. Each of the plurality of vent holes Vt may have a circular or elliptical shape, but the shape of the vent hole Vt is not limited thereto, and the vent hole Vt may be formed in various shapes such as a quadrangular, triangular, or hexagonal shape. Each of the plurality of vent holes Vt is formed such that a maximum diameter of the vent hole Vt is nearly equal to a thickness of the semiconductor module 200.

Therefore, the wind generated by the intake fans 130 not only flows between the heat radiating fins 113 of the heatsink 110 after passing through the quadrangular box member 123, but also passes through the vent holes Vt formed in the inclined lateral surface 123a of the quadrangular box member 123, and passes through an upper region of the base 111 of the heatsink 110, thereby dissipating heat of the semiconductor modules 200, the base 111, and the heat radiating plates 140 to the outside.

In FIGS. 1 to 3, the auxiliary duct 125 guides flow paths of the wind passing through the vent holes Vt formed in the inclined lateral surface 123a of the quadrangular box member 123, and the auxiliary duct 125 may be formed on the inclined lateral surface 123a of the quadrangular box member 123 so as to surround the vent holes Vt. The auxiliary duct 125 may include a pair of triangular members 125a and a guide surface 125b.

The pair of triangular members 125a may be provided on the inclined lateral surface 123a of the quadrangular box member 123 so as to be spaced apart from each other at a predetermined interval. The pair of triangular members 125a may be spaced apart from each other at a predetermined interval with the plurality of vent holes Vt disposed therebetween. The pair of triangular members 125a may be attached to the inclined lateral surface 123a of the quadrangular box member 123 by a separate fastening member having a surface shape, but the present invention is not limited thereto.

The guide surface 125b may be formed to connect the pair of triangular members 125a. The guide surface 125b may be formed on the same plane as a second imaginary surface V12 that horizontally extends from an upper end of the semiconductor module 200 which is opposite to a lower end of the semiconductor module 200 being in surface-to-surface contact with one surface of the base 111 of the heatsink 110.

Therefore, one end of the auxiliary duct 125, which faces the base 111 or the semiconductor module 200, is opened, such that the wind, which is generated by the intake fans 130 and passes through the vent holes Vt, may flow to the base 111 and the semiconductor modules 200 through the opened end of the auxiliary duct 125. That is, the auxiliary duct 125 prevents the wind from leaking to the outside, and the wind flows toward the base 111 and the semiconductor module 200.

Meanwhile, auxiliary vent holes (not illustrated) and covers CV may be provided on the guide surface 125b of the auxiliary duct 125 in order to adjust intensity of the wind provided to the upper region of the base 111.

The plurality of auxiliary vent holes may be formed. The number of auxiliary vent holes may vary as necessary. The number of auxiliary vent holes may vary in order to variously adjust intensity of the wind. That is, the wind generated by the intake fans 130 passes through the vent holes Vt formed in the inclined lateral surface 123a of the quadrangular box member 123, and a predetermined amount of wind is dispersed to the outside through the auxiliary vent holes, and as a result, the intensity of the wind with respect to the upper region of the base 111 is decreased.

The cover CV is provided to increase the intensity of the wind which has been decreased with respect to the upper region of the base 111, and the number of covers CV may be equal to the number of auxiliary vent holes. That is, the cover CV may be provided for each auxiliary vent hole. The cover CV may be fastened onto the guide surface 125b of the auxiliary duct 125 by a threaded engagement, but the present invention is not limited thereto. The cover CV may close the auxiliary vent hole when the cover CV is coupled to the guide surface 125b of the auxiliary duct 125b, such that the cover CV prevents the wind from flowing to the outside through the auxiliary vent hole, thereby increasing the intensity of the wind with respect to the upper region of the base 111.

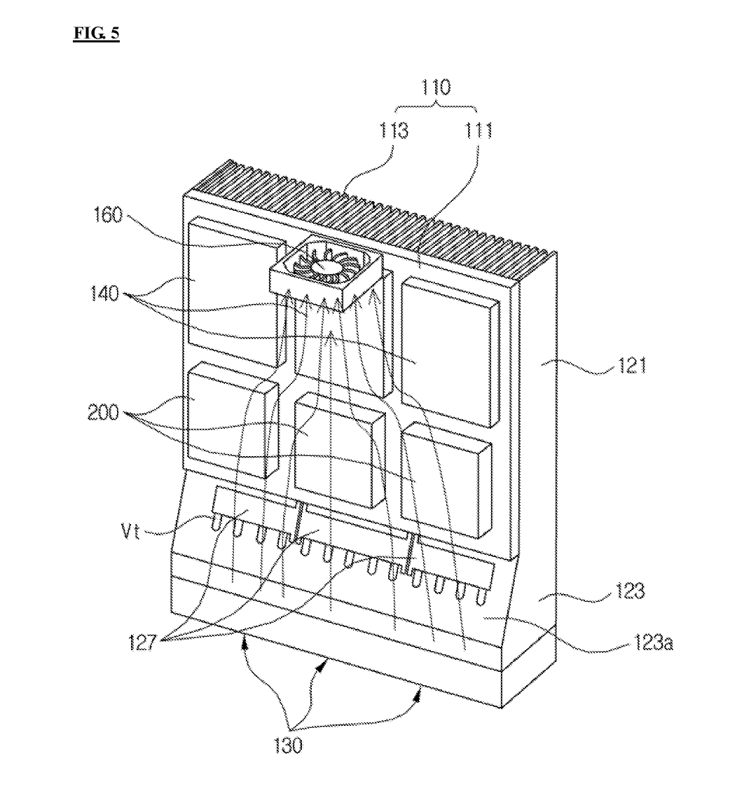

Meanwhile, referring to FIG. 5, the opening and closing members 127 for adjusting the intensity of the wind with respect to the upper region of the base 111 may be provided on the inclined lateral surface 123a of the quadrangular box member 123.

The opening and closing member 127 may be slidably connected to the inclined lateral surface 123a of the quadrangular box member 123. The plurality of opening and closing members 127 may be provided. For example, the number of opening and closing members 127 may be equal to the number of semiconductor modules 200. This configuration enables the opening and closing member 127 to open and close the vent hole Vt to a predetermined degree. The opening and closing members 127 may be positioned at normal times at positions for opening the vent holes Vt, and one or more of the opening and closing members 127 may slide to positions for closing the plurality of vent holes Vt facing a predetermined region of the upper side of the base 111 in order to decrease the intensity of the wind when adjusting the intensity of the wind.

Therefore, the intensity of the wind in the predetermined region of the upper side of the base 111 is decreased, and the intensity of the wind in a particular region of the upper side of the base 111 is increased. Here, the predetermined region may be a region in which the semiconductor module 200, which generates a relatively small amount of heat, is positioned, or may be a region in which the semiconductor module 200, which generates a relatively large amount of heat, is positioned.

The opening and closing member 127 may slide automatically or manually. Here, a motor module (not illustrated) capable of sliding the opening and closing member 127 may be provided in the quadrangular box member 123.

Referring to FIG. 2, the intake fans 130 generate the wind for dissipating the heat of the heatsink 110, the heat radiating plates 140, and the semiconductor modules 200 to the outside, and the intake fans 130 may be provided at the other end of the quadrangular box member 123 which is opposite to one end of the quadrangular box member 123 connected to the pair of wall members 121.

The intake fan 130 may generate the wind while rotating. The intake fan 130 may be sized to correspond to a width of the other end of the quadrangular box member 123. The plurality of intake fans 130 may be disposed in a row in the longitudinal direction of the quadrangular box member 123. As described above, the wind generated by the intake fans 130 may dissipate heat while passing through the quadrangular box member 123 and flowing between the heat radiating fins 113 of the heatsink 110, or may dissipate heat of the semiconductor modules 200 and the heat radiating plates 140 while passing through the vent holes Vt formed in the inclined lateral surface 123 of the quadrangular box member 123 and flowing through the upper region of the base 111 of the heatsink 110.

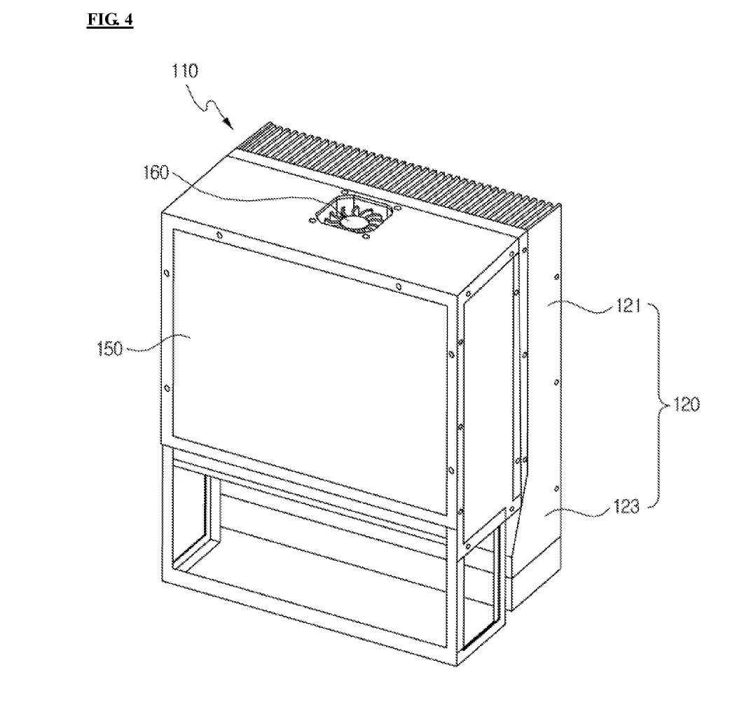

Meanwhile, referring to FIG. 4, the casing 150 may be formed to surround the upper region of the base 111 of the heatsink 110 in order to allow the wind, which passes through the upper region of the base 111 of the heatsink 110, to flow in one direction without being dispersed in all directions.

The casing 150 may include an upper portion having a quadrangular box shape opened at one side and a lower end thereof, and a lower portion having various types of frame members extending perpendicularly to the upper portion from the upper portion. One surface of the upper portion of the casing 150 may be coupled to an edge of one surface of the base 111 of the heatsink 110. Therefore, the casing 150 surrounds the semiconductor modules 200 and the heat radiating plates 140.

An exhaust port may be formed at an upper end of the upper portion of the casing 150. The exhaust fan 160 may be provided in the exhaust port at the upper end of the upper portion of the casing 150. Referring to FIG. 5, it can be seen that the wind generated by the intake fans 130 passes through the vent holes Vt, passes through the upper region of one surface of the base 111 of the heatsink 110, and is discharged by the exhaust fan 160. That is, the casing 150 and the exhaust fan 160 guide a flow path of the wind, thereby effectively dissipating the heat in the upper region of the one surface of the base 111 of the heatsink 110.

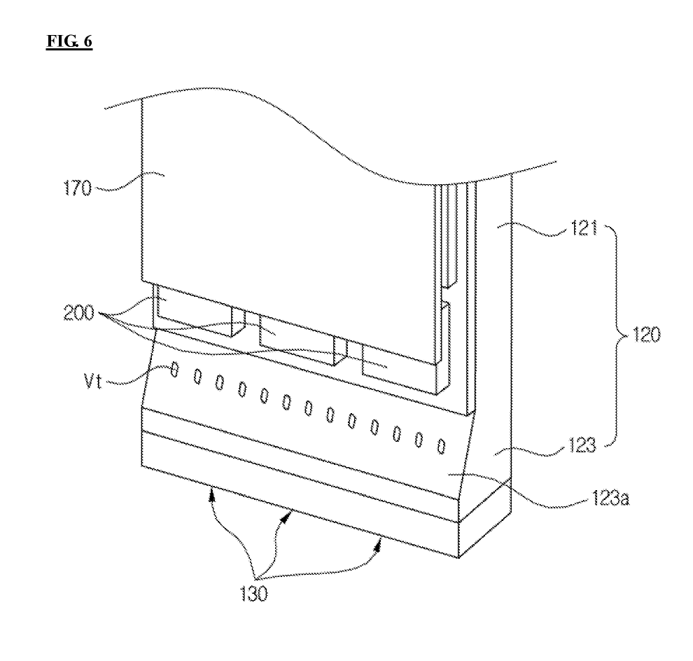

Referring to FIGS. 5 and 6, a bus bar 170 is provided in the upper region of one surface of the base 111 in order to supply electric current to the plurality of semiconductor modules 200. Here, heat generated by the bus bar 170 may adversely affect performance of the semiconductor modules 200, but according to the heat dissipation apparatus 100 for a semiconductor module according to the exemplary embodiment of the present invention, the wind generated by the intake fans 130 may also dissipate heat of the bus bar 170 to the exhaust fan 160 by using the structure having the duct unit 120, the casing 150, and the exhaust fan 160, thereby preventing performance of the semiconductor modules 200 from deteriorating due to the heat of the bus bar 170.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A heat dissipation apparatus for a semiconductor module, the heat dissipation apparatus comprising:
a heatsink which is provided to be in surface-to-surface contact with a semiconductor module;
a duct unit which includes a pair of wall members which extends perpendicularly to an edge of the other surface of the heatsink from the edge of the other surface of the heatsink which is opposite to one surface of the heatsink which is in surface-to-surface contact with the semiconductor module, and a quadrangular box member which is formed in a quadrangular box shape opened at both ends thereof, in which two sides of the opened ends of the quadrangular box member are connected to the wall members, respectively, and any one surface, among surfaces for constituting the quadrangular box shape, is formed to be inclined; and
an intake fan which is provided at the other end of the quadrangular box member,
wherein a vent hole is formed in the inclined lateral surface of the quadrangular box member so that the wind generated by the intake fan passes through the quadrangular box member and is provided to the semiconductor module when the intake fan operates to dissipate heat of the semiconductor module.

2. The heat dissipation apparatus of claim 1, wherein the number of vent holes is more than one.

3. The heat dissipation apparatus of claim 2, wherein the plurality of vent holes is formed on the same line as an imaginary surface that horizontally extends from one surface of the heatsink, and the plurality of vent holes is arranged in a row in a longitudinal direction of the inclined lateral surface of the quadrangular box member.

4. The heat dissipation apparatus of claim 3, wherein each of the plurality of vent holes is formed in a circular or elliptical shape.

5. The heat dissipation apparatus of claim 4, wherein each of the plurality of vent holes has a maximum diameter equal to a thickness of the semiconductor module.

6. The heat dissipation apparatus of claim 1, wherein the duct unit further includes an auxiliary duct which guides a flow path of the wind passing through the vent hole and is formed on the inclined lateral surface of the quadrangular box member so as to surround the vent hole.

7. The heat dissipation apparatus of claim 6, wherein the auxiliary duct includes:
a pair of triangular members which is provided on the inclined lateral surface of the quadrangular box member so as to be spaced apart from each other at a predetermined interval; and
a guide surface which connects the pair of triangular members and is formed on the same plane as an imaginary surface that horizontally extends from an upper end of the semiconductor module which is opposite to a lower end of the semiconductor module being in surface-to-surface contact with one surface of the heatsink.

8. The heat dissipation apparatus of claim 7, wherein an auxiliary vent hole is formed in the guide surface to adjust intensity of the wind passing through the vent hole, and the auxiliary vent hole is opened and closed by a cover.

9. The heat dissipation apparatus of claim 1, wherein the duct unit further includes an opening and closing member which is slidably connected to the inclined lateral surface of the quadrangular box member and opens and closes the vent hole.

10. The heat dissipation apparatus of claim 9, wherein the number of opening and closing members is more than one so as to open and close the vent hole to a predetermined degree.

11. The heat dissipation apparatus of claim 1, wherein one surface of the heatsink is divided into a first region which occupies at least a part of one surface of the heatsink, and a second region which occupies the remaining part of one surface of the heatsink, the semiconductor module is provided in the first region, and a heat radiating plate is provided in the second region.

12. The heat dissipation apparatus of claim 11, further comprising:
a casing which is coupled to an edge of one surface of the heatsink so as to surround the semiconductor module and the heat radiating plate.

13. The heat dissipation apparatus of claim 12, wherein the casing has an exhaust port.

14. The heat dissipation apparatus of claim 13, wherein an exhaust fan is provided in the exhaust port so that the wind generated by the intake fan passes through the vent hole, passes through an upper region of one surface of the heatsink, and is discharged through the exhaust port.

15. The heat dissipation apparatus of claim 1, wherein the heatsink includes:
a base which has one surface formed to be in surface-to-surface contact with the semiconductor module; and
a plurality of heat radiating fins which extends perpendicularly to the other surface of the base from the other surface of the base which is opposite to one surface of the base.
